(19) United States
(12) Patent Application Publication
(10) Pub. No.: US 2006/0158360 A1
(43) Pub. Date: Jul. 20, 2006

(54) Digital to analog converter

(75) Inventor: Joseph Briaire, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., BA Eindhoven (NL)

(21) Appl. No.: 10/560,645

(22) PCT Filed: Jun. 11, 2004
(86) PCT No.: PCT/IB04/50889

§ 371 Date: Dec. 13, 2005

(30) Foreign Application Priority Data
Jun. 18, 2003 (EP) 03101787.4

(51) Int. Cl. H03M 1/66

(52) U.S. Cl. 341/144

(57) ABSTRACT

A digital to analog converter comprises a plurality of conversion elements as well as a reference conversion element and further comprises mismatch calibration unit for calibrating at least one of the conversion elements in response to a comparison of that element's output with the output of the reference conversion element. The mismatch calibration unit calibrates the source with respect to static and dynamic mismatch by determining under varying circumstances the difference between outputs from a conversion element and reference conversion element.

The invention concerns a digital to analog converter and a method of converting a digital signal to an analog signal.

Digital to analog converters comprise a plurality of individual sources, usually, but not exclusively, 1-bit current sources, which are used to construct an analog signal representative of digital input code. The resulting accuracy of the analog signal depends on several factors. One of these factors is the matching between individual sources, which determines the level at which all sources operate and the degree to which they behave identically with respect to each other. This phenomenon is referred to in the art as “mismatch- level”. This mismatch level comprises two contributing factors: static mismatch and dynamic mismatch. Static mismatch is defined as a difference which can be determined between the individual sources when the digital input code of each source does not change (i.e. is static). Dynamic mismatch is defined as the non-static behavioral difference between individual sources whose digital input code is changed identically with respect to one another. Dynamic mismatch is also referred to in the art as “glitch” mismatch. In current high speed (also referred to as high frequency) D/A converters, where the signal to be converted is also of a high frequency, dynamic mismatch appears to be the dominating factor. It is added, that where the signal to be converted is of a low frequency, or even static, the static mismatch is an important factor.

Known techniques for calibrating for mismatch involve the use of selection algorithms which have the effect of averaging out mismatch between sources. For example, U.S. Pat. No. 5,406,283 proposes a technique for correcting for minor mismatches between unit digital to analog conversion elements in a digital to analog converter, whereby the digital to analog converter comprises means for cyclically selecting successive different permutations of the unit elements for converting each value of the digital signal to thereby randomize mismatches between unit elements. Such a cycling means, however, does not address the problem of removing or accounting for the errors in each unit element. This system suffers from the disadvantage that, in digital to analog converters comprising a large number of unit elements, as is customary, the degree to which the error associated with each element can be adequately cancelled is limited.

An object of the present invention is to provide an alternative scheme for calibrating for mismatch which is improved in accuracy over known methods, and which is in particular suited for suppression of dynamic mismatch in high speed, high frequency converters.

The above and further objects are achieved by the digital analog converter as defined in claim 1. Thus defined the converter of the present invention uses a feedback of the result of a comparison with a reference to provide accurate mismatch calibration. The scheme is applicable to static mismatch calibration, either separately or in combination.

The invention is further directed to a method of converting digital to analog signals as defined in claim 12 and a mismatch calibration unit for a digital to analog converter according to claim 15.

In order that the invention may be more fully understood, embodiments thereof will now be described by way of example only, with reference to the figs. in which:

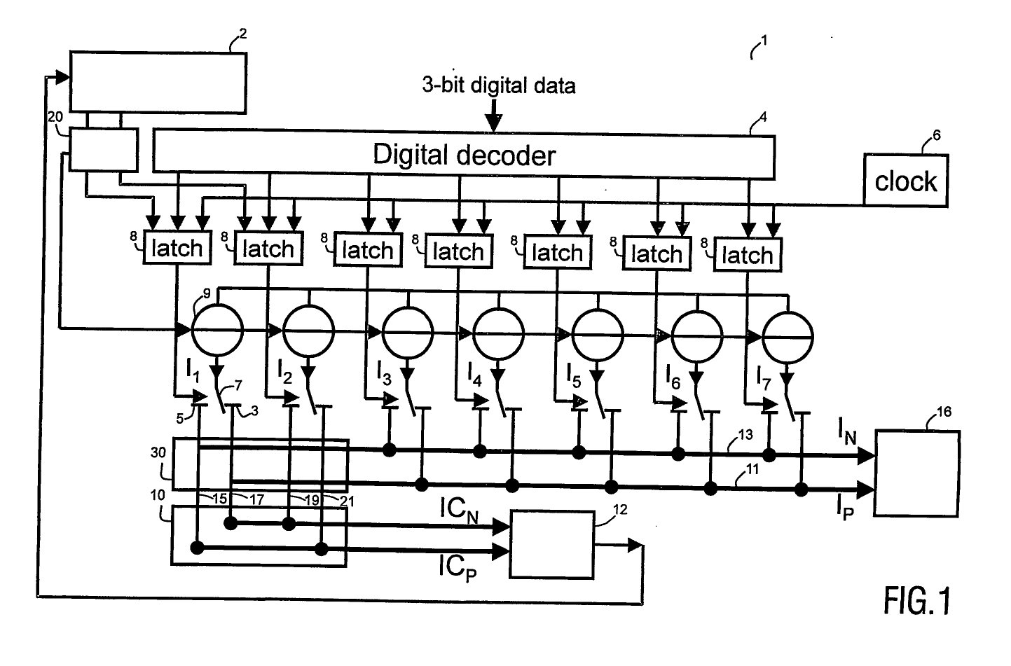

FIG. 1 shows a digital to analog converter according to a first embodiment of the present invention;

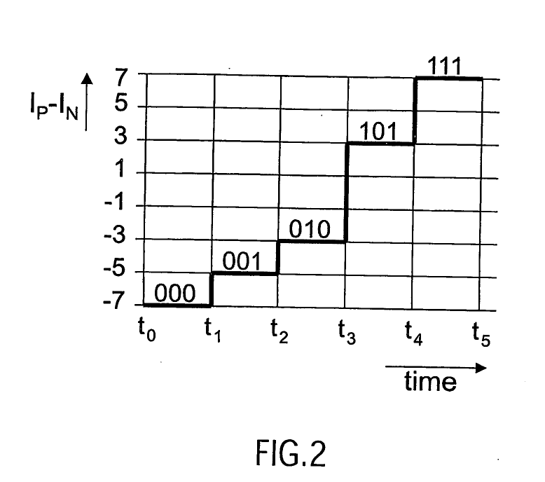

FIG. 2 shows the output signal of a digital to analog converter according to the present invention;

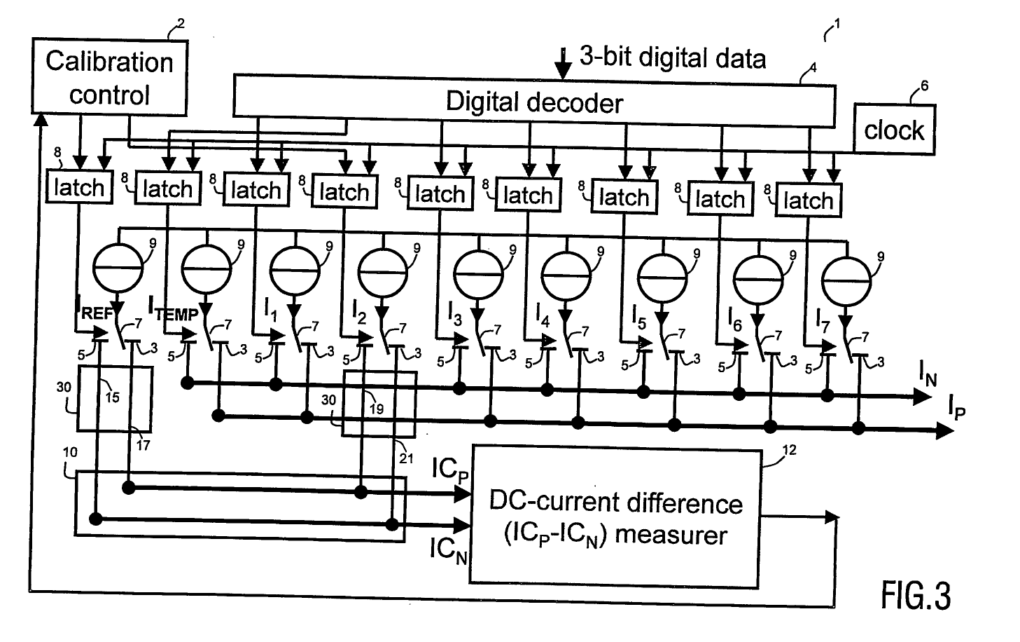

FIG. 3 shows a digital to analog converter according to a further embodiment of the present invention;

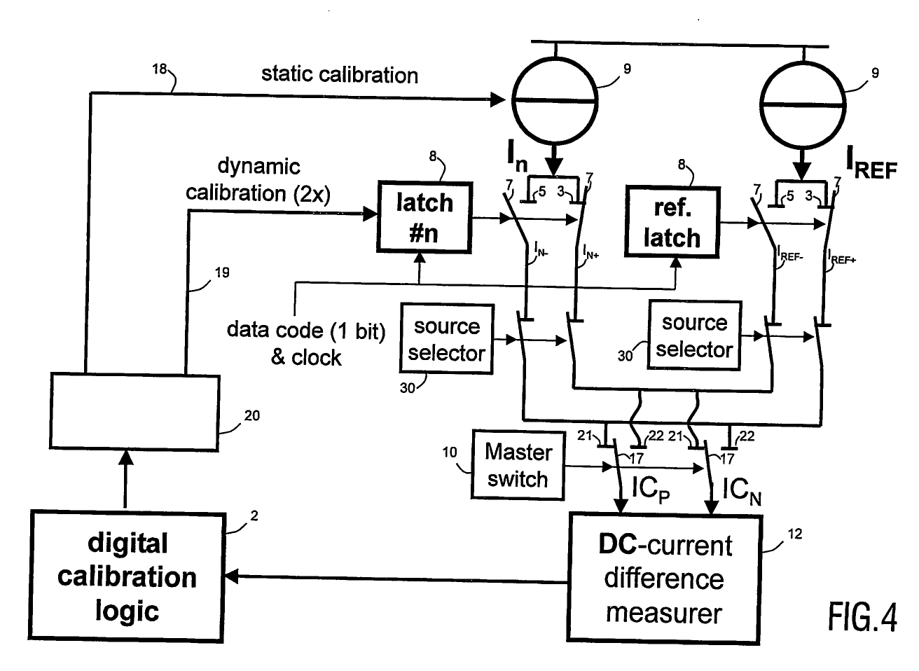

FIG. 4 shows details of the architecture of the calibration circuit of the present invention;

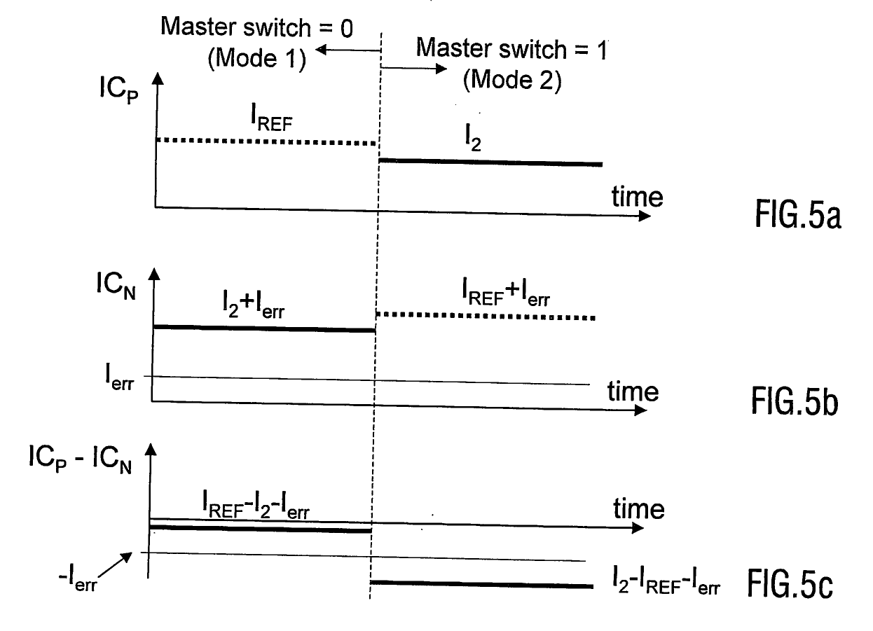

FIG. 5 shows an example of static calibration of a conversion element with respect to a reference conversion element;

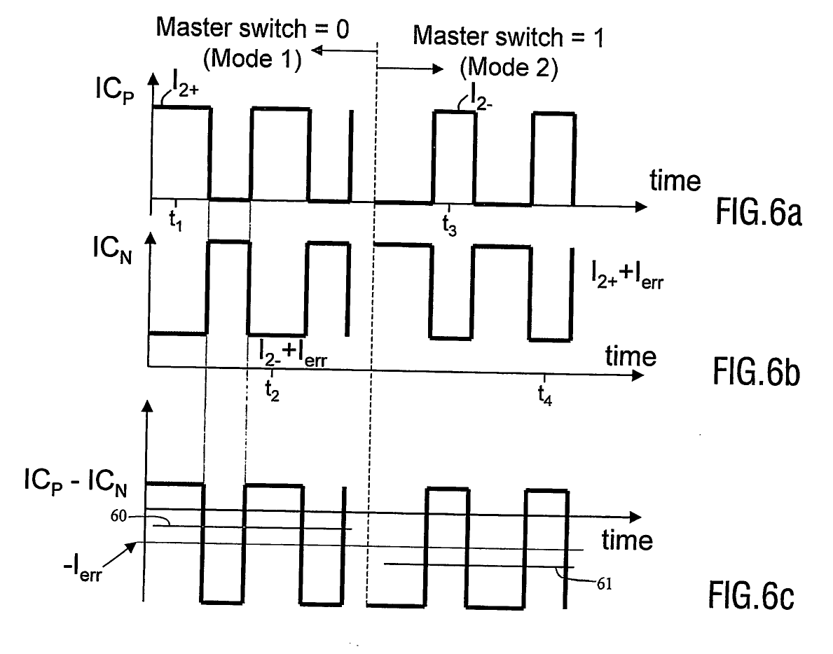

FIG. 6 shows an example of the duty cycle calibration of a conversion element; and

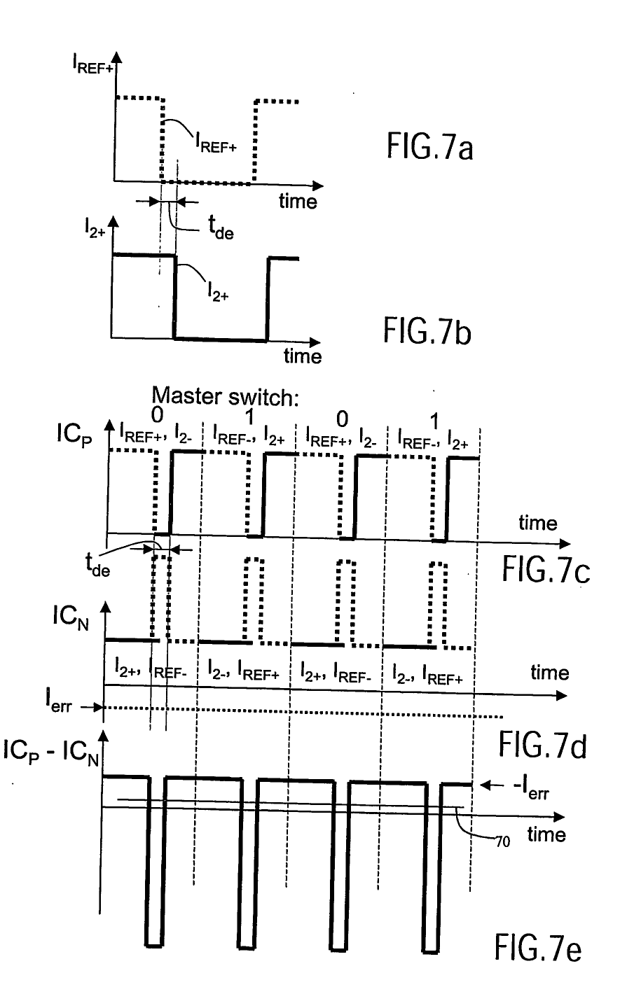

FIG. 7 shows an example of the switching delay calibration of a conversion element with respect to a reference conversion element.

FIG. 1 shows a three bit digital to analog converter 1. The digital to analog converter 1 comprises a digital decoder 4, a plurality of latches 8, which are responsive to a clock signal generated by clock 6, and a plurality of switches 7, which are responsive to a latch signal generated by the latches 8. Each conversion element 9 is provided with an associated switch 7. Preferably, the digital decoder unit 4 receives the multi bit digital input signal, and the set of latches 8, each of which is configured to selectively connect a respective one of the conversion elements 9 to the output 11, 13, 16 in response to a respective signal output by the digital decoder. Preferably, also, each latch 8 is configured to connect its respective conversion element 9 to either of a first or a second input IN, IP to the output unit 11, 13, 16, wherein the output unit 11, 13, 16 is adapted to combine the signals from the first and second inputs IN, IP to provide the output analog signal. The conversion elements provide an analog signal which is directed, depending on the latch signal, onto a first output line 11 or a second output line 13 to output node 16. Also provided is a calibration circuit for calibrating a second conversion element with respect to a first reference conversion element. The calibration circuit comprises a master switch 10 for selecting between the first and second current carriers, source selector switches 30 to select the individual currents I₁ and I₂, a direct current (DC) current measurer 12 for measuring the difference between the direct current IC_{P} and IC_{N}. The function of the source selector switches 30 is to decouple the current sources for calibration, that is, in the illustrated example, I1 and I2, from the output signal lines 11, 13, and couple them to the calibration circuitry via lines 15, 17 for source I1 acting as reference source and via lines 19, 21 for source I2 to be calibrated. The source selector switch, thus, enables one source I1, to be distinguished from another source I2. As mentioned previously, the latch signals govern whether the current source is directed onto the first or second output line 11, 13. As seen in FIGS. 1, 3 and 4, the current generated by the current sources, in particular, as shown in the Figs., I1, I2 and IREF is directed via one of two legs depending on the latch signal. The current carried by the first leg of each current source, seen in the Figs. as the right hand leg, is referred to as I1+, I2+ or IREF+, respectively, while the current through the other second leg is referred to as I1−, I2− or IREF−, respectively. Since, the latch signal switches the current from either the first leg or the second leg, at any one time either the first or second leg will carry the current I1, I2 or IREF, respectively, whilst the current carried in the other leg will be zero. With reference to FIG. 1, the current carried by line 15 is referred to as I1−, by line 17 as I1+, by line 19 as I2− and by line 21 as I2+. It is seen in the Figs., that the same nomenclature is assigned to the respectively legs 19, 21 of the source to be calibrated 12. For example, the currents carried by the legs of source number 2, are labeled in FIGS. 4, as I2+ and I2−. In the following description, for the sake of simplicity and consistency, it is assumed that if the data signal of a latch is “1”, the latch will set the switches such that the “+” leg (that is the second leg) carries the source current and the “−” leg (that is the first leg) carries no current. And, therefore, if the data signal is “0”, the “−” leg will carry the source current while the “+” leg is zero. It is noted that this nomenclature is also used, and intended to have the same meaning, in FIGS. 6 and 7.

The difference between the measured DC current levels on the first and second output lines is used to determine the static and various dynamic errors between a first and second conversion element. The difference measured by the DC current measurer is provided in the form of a digital signal to a calibration control circuit 2, which provides, in response to the measured difference, a calibration signal to the second conversion element so that the static and various dynamic errors accounted for are matched between the second and the reference conversion element.

By way of example only, FIG. 1 shows a three bit digital to analog converter is constructed to convert digital data 000 to 111. To convert three bit digital data to an analog signal seven conversion elements 9, shown as I1 to I7, are required (i.e. 2³−1 conversion elements). In practice, it will be understood that the digital to analog converter is constructed to convert data having a larger number of bits is larger than three. This is realized by providing an appropriate number of sources and latches and appropriate control circuitry. The invention is not limited in respect of the number of bits the data for conversion comprises.

In FIG. 1, the conversion elements are current sources. However, the invention is not limited in this respect, and the conversion elements may also be voltage sources, or indeed any group of elements which function as a source when subject to an appropriate signal. In particular, that a nominal one bit analog signal is produced from the switching of a nominal 1 bit unit, and that the signal produced can be measured an tuned to be made identical to another unit. If other sources are chosen, the architecture shown in FIG. 1 is adapted appropriately, however, the calibration circuit as described herein below, follows the same principles. For example, if voltage sources are chosen, it is required to measure voltage instead of current. It is noted however, that when current sources are used, either the current or the voltage may be measured directly.

In one embodiment, the sources are chosen to be substantially equal to one another, for example a series of substantially identical unit sources. However, in an alternative embodiment, the sources are chosen so that a combination of already calibrated sources are used to calibrate the next source. For example, a series of sources are chosen whereby the current generated by a source is a multiple, for example double, of the current generated by the previous source. Thus for current sources, the current through each source doubles each time so that I1=1 current unit, I2=2 current units, I3=4 current units, I4=8 current units, etc. This binary architecture has particular application to digital to analog converters. In this particular embodiment, a reference source is also provided, wherein the current through the reference, Iref=1 unit. The reference source is then used to calibrate the source I1=1 unit. Once I1 is calibrated using IREF, the combination of IREF and I1 is used as the reference source IREF2 to calibrate, I2, which generates a current of 2 units. And subsequently, a combination of IREF, I1 and I2 is used as the reference source IREF3 to calibrate I3, which generates a current of 4 units, and so on, until the largest current source is calibrated with respect to the other sources.

The present invention is applicable to any digital to analog converter comprising a series of theoretically identical sources, which are not completely identical in practice, and therefore require calibration. Thus, the present invention has application to conventional, that is Nyquist converters, and also sigma delta type converters, in particular to the D/A converters conventionally used in the feedback loop.

With reference also to FIG. 4, conversion element selection logic 4, 8 is provided to select the conversion element and the location to which the conversion element directs its output. The conversion element selection logic preferably comprises a digital decoder 4 and a latch 8. The function of latch 8 is to drive switch 7 into one of two positions. In a first position, the latch causes the switch 7 to direct the current (or voltage if voltage sources are used) via contact 3 into a first leg I1+. During normal operation, when this source is not calibrated, this leg is connected to the first output line 11, which carries current IP. During calibration the source selector 30 connects this leg I1+ to the master switch 10. In a second position, the latch 8 causes the switch 7 to direct the current (or voltage if voltage sources are used) via contact 5 into a second leg I1−. Again, during normal operation, this second leg is connected to the second output line 13 that carries current IN. And during calibration this second leg I1− is connected to the other side of the master switch 10. The latches 8 allow the current to flow through the one leg I1+ or the other I1−. Hence, the selection of the latches determines the analog output of the converter. The digital decoder, on the basis of the input digital data, determines how each source should be switched. The latch controls the actual switching moment, since it is important that all switches to be switched switch at substantially the same moment in time. The dynamic calibration signal generated by the calibration circuit 2 is provided to the latch 8. The output on the first and second output lines IP and IN, respectively, is equal to the analog signal current IP and its complement IN. Thus, the analog output signal is the difference between the current on the first output line and the current on the second output line, that is IP−IN.

The master switch 10 is a double switch comprising two switching elements, as shown and described in more detail with reference to FIG. 4. Both switching elements are controlled by the same signal. The master switch 10 is used to exchange the currents that flow through ICP and ICN. In a first switching position, also referred to as the “zero” position, or mode 1, both switching elements are directed such that ICP carries the current from source IREF while ICN carries the current from In. In a second switching position, also referred to as the “1” position, or mode 2, both switching elements are directed such that ICP carries the current from source In while ICN carries IREF. It is noted however, that this also depends on the position of the latches. Preferably, for optimal operation of the calibration circuitry, it has been found that it is important that the latches 8 of the sources I1-I7 that are calibrated and the latches 8 of the reference sources IREF are such that the sum of the calibration currents flows through one leg of the master switch, either ICP or ICN, while the sum of the reference currents flows through the other. The master switch 10 is further connected to the DC current measurer 12. Thus, at any one time, one leg of the DC meter 12 is connected to the reference sources while the other is connected to the sources to be calibrated. The function of the master switch 10 is described in more detail with reference to FIGS. 5-7.

The DC current measurer 12 preferably comprises a current measurer and an analog to digital converter to generate a digital signal on the basis of the measured current. Preferably, a sigma delta analog to digital converter is used. The master switch 10 determines the input to the DC current measurer so that offset and measurement time do not have to be taken into consideration in the current measurement. As offset and measurement time are not factors in the current measurement, this allows accurate current measurement to take place. The DC current measurer 12 is described in further detail herein below with reference to FIGS. 4-7.

As mentioned the digital output from the DC current measurer 12 is provided to a calibration circuit 2. The calibration circuit 2 includes logic elements which generate a signal to correct the signal source. The calibration signal is supplied to the conversion element to be calibrated I2 and preferably also the reference element I1. In a particular embodiment, the calibration signal is provided to a correction circuit 20. The correction circuit 20 may, for example, comprise a low pass filter with an adjustable parameter. For example a resistor-capacitor (RC) filter may be provided, wherein the capacitance or resistance is variable to provide an adjustable time constant. In a discrete signal domain, the low pass filter acts as an adjustable delay that can be placed at the output of the latch of the conversion element to be calibrated. In this way the resistance is changed discretely, for example with a binary code generated by the calibration circuit 2. The binary code is provided to a resistor bank, which is a series of resistors in parallel, that are selected individually by a switch in response to the binary code. The bank of resistors may include resistors having different sizes, however this is not essential. In an alternative embodiment, the correction circuit is not necessary, and is dispensed with. In the alternative embodiment, the DC level of the signal source is not addressed by correcting the individual source to be calibrated. In the alternative embodiment, the net error of all sources is digitally calculated by the calibration circuit 2 for each data sample, including error calculations for the static and various dynamic errors, and generate a calibration signal which acts on an independent set of sources (not shown) to cause the independent set of sources to generate a signal equal to the calculated net error which is subtracted from the set of sources I1-I7.

When calibration is carried out, and how frequently it is carried out will depend on the particular application of the digital to analog converter. In one embodiment, calibration is carried out once during start up, that is when the power is turned on. Alternatively, however, depending on the circumstances, it may be necessary to carry out calibration at more frequent intervals, for example, every second, minute or hour, depending on the particular application. In the embodiment shown in FIG. 1, the digital to analog converter is not operational during calibration. This is also referred to as “offline” calibration. However, in the embodiment shown in FIG. 3 calibration may be carried out whilst the converter is functioning. This is also referred to as “online” calibration.

FIG. 2 shows the output signal of a digital to analog converter according to the present invention. As mentioned above, the output signal of the digital to analog converter is equal to the difference between the current carried on the first output line 11, carrying current IP and the second output line 13, carrying current IN, i.e. the output signal from output terminal 16 is IP−IN. In FIG. 2, the output signal (IP−IN) in for instance milli Amperes is plotted against time. In FIG. 2, the current sources used to generate the output signal are substantially identical and each generate a current of substantially equal to 1 milli Ampere, that is I1=I2= . . . =I7=1 milli Ampere.

For each digital input code, the digital decoder 4 determines the decimal value of the digital input code to establish how many of the conversion elements are to be switched to provide an analog signal current IP carried by the first output line 11. It does not matter which of the conversion elements are switched provided that the sum of the conversion elements switched is equal to the decimal value of the digital input code. Those conversion elements which are not to be switched to the analog signal output line 11 are switched to provide the complement of the analog signal current IN on the second output line 13. In the example shown in FIG. 1, for all digital input codes, all conversion elements are switched to either the first or the second output line. This is not however essential, although it is preferred because it produces a constant load on the power supply.

Thus, with reference further to FIG. 2, in normal operation, the digital input code 000 causes digital decoder 4 to generate a signal to cause each latch 8 associated with each source I1-I7 to direct current to the second output line IN. This is achieved by switch 7 moving to the right in FIG. 1 to contact with contact element 3. It will be understood, however, that in calibration mode, the source selectors 30 in calibration position will cause the currents to be decoupled from IN and IP, as described above with reference to FIG. 1. It is noted that FIG. 1 does not explicitly show whether the digital to analog converter is in normal mode or calibration mode.

In normal mode, with the switch 7 moved to the right in FIG. 1, each current source generates 1 milli Ampere of current. Thus, at output terminal 16, the total current carried on second output line 13, IN is equal to 7 mA, and the total current carried on first output line 11, IP is 0 mA. Thus, for digital input code 000, the output signal is −7 mA because IP−IN=−7 mA. For digital input code 001, the digital decoder 4 generates a signal to cause each latch 8 associated with each source I1-I6 to direct current to the second output line 13, and I7 to direct current to the first output line 11. Thus, IP=1 mA and IN=6 mA. Thus, IP−IN=−5 mA. The same principle applies to digital input codes 010, 011, 100, 101, 110 and 111. So, for example, the digital decoder 4 generates from digital input code 111 a signal to latches 8 associated with conversion elements I1-I7, to direct the current from all conversion elements I1-I7 to the first output line 11 to form current IP=7 mA. Thus, IP−IN=7−0=7 mA. This is achieved by latch 8 causing switch 7 to move to the left to contact element 5.

As can be seen from FIG. 2, at time, t0, a digital input code of 000 produces an output of −7 milli Amperes. At time, t1, a digital input code of 001 produces an output of −5 mA. At time, t2, a digital input code of 010 produces an output of −3 mA. At time, t3, a digital input code of 101 produces an output of 3 mA. At time, t4, a digital input code of 111 produces an output of 7 mA.

The results shown in FIG. 2 are obtained using an analog to digital converter which has been calibrated using a calibration circuit according to the present invention. It is seen that, in particular, there is no delay between the switching of the conversion elements at times, t=t1-t4 and the attainment of the appropriate output signal. This is in contrast to conventional digital to analog converters where a delay is seen between the switching of the elements and attainment of the appropriate output signal. It is understood that such a delay leads to one particular type of dynamic mismatch. Thus, from FIG. 2 it is seen that the problems associated with dynamic mismatch in conventional converters have been overcome. The calibration of the converter with respect to static and dynamic mismatch is described in more detail with reference to FIGS. 5-7.

FIG. 3 shows a digital to analog converter according to a further embodiment of the present invention. Those elements in FIG. 3 having the same reference numerals as those shown in FIG. 1, are not described again with reference specifically to FIG. 3 unless details differ from those discussed in FIG. 1 or aspects thereof are expanded upon. In the embodiment shown in FIG. 1 “off-line” calibration takes place, that is the source that is to be calibrated is taken out of normal operation (off-line). In the embodiment shown in FIG. 3 calibration is permitted to take place which allows normal operation of the digital to analog converter to continue during calibration. So, although, the calibration shown in FIG. 3 is not strictly “on-line”, because the source being calibrated is not available for normal operation, operation of the converter is allowed to continue due to the presence of a temporary source ITEMP, as described below.

In the embodiment shown in FIG. 3, a reference conversion element IREF is provided against which conversion elements I1-I7 are calibrated. In the particular, embodiment shown reference conversion element IREF is being used to calibrate conversion element I2. An additional conversion element ITEMP is provided together with an associated latch. Further, digital decoder 4 is provided with a circuit to determine which of the conversion elements is being calibrated and to forward the digital control signal instead of to the conversion element I2 being calibrated to the temporary conversion element ITEMP in its place. In this way, the operation of the converter continues uninterrupted by the calibration procedure. It is noted that the reference conversion element IREF is not essential to this embodiment. Indeed, as discussed above with reference to FIG. 1, any one of the conversion elements I1-I7 may be used as the reference element against which the other elements are calibrated. It is not necessary to provide an additional reference element dedicated to calibration alone. In this case however, to allow normal operation of the digital to analog converter to continue during calibration of a source, two temporary elements are provided (the second of which is not shown in FIG. 3) to replace those which are involved with the calibration at any one time. Further, the digital decoder is arranged to provide the digital control code to the appropriate temporary conversion elements. In calibration mode, the source selector 30 selects legs 15, 17, 19, 21 so that the current carried on first leg 15 with respect to the reference source IREF is IREF+, on second leg 17 is IREF−, and with respect to the source to be calibrated I2, the current carried on the first leg is I2+ and the second leg is I2−.

FIG. 4 shows details of the architecture of the calibration circuit of the present invention. Those elements in FIG. 4 having the same reference numerals as those shown in FIG. 1, are not described again with reference specifically to FIG. 4 unless details differ from those discussed in FIG. 1 or aspects thereof are expanded upon. Conversion elements In and IREF are shown, wherein conversion element In is calibrated with respect to conversion element IREF. In calibration mode, the first output line IN+ of conversion element In is connected to the first output line IREF+ of conversion element IREF. The second output lines In−, IREF− are similarly connected. A source selector 30 is provided. The function of the source selector 30 is to select whose outputs of which sources are directed to the master switch 10. Thus, in the embodiment shown in FIG. 4, the selector switch 30 selects the outputs of conversion elements In and IREF, for input to master switch 10. It will be understood that subsequent to calibration of conversion element In, the selector element will select together with IREF, In+1, etc until the necessary elements have been calibrated. The source selector 30 is arranged to select both the first and second output lines IN+, IN−, IREF+, IREF− for each source selected. The master switch 10 has two modes. In the first mode, as shown in FIG. 4 both switch elements 17 are in the left hand position. In the second mode, both switch elements 17 are in the right hand position.

The calibration as herein below comprises three stages and in the first stage static calibration is carried out The static calibration control signal 18 as determined by the digital calibration logic on the basis of the DC current difference measurer measured on the basis of the master switch selection, is provided via feed back to the conversion element In. The dynamic calibration comprises two stages: calibration of the duty cycle of the conversion element to be calibrated with respect to the reference element, and calibration of the switching delay of the conversion element to be calibrated with respect to the reference element. Each calibration gives rise to a dynamic calibration control signal 19 which is provided via feed back to the respective latch 8. The dynamic calibration control signal 19 thus comprises two components: the first representing duty cycle calibration and the second representing switching delay calibration. It is noted that FIG. 4 shows the embodiment where each conversion element and latch is corrected individually. However, the invention as mentioned, is not limited in this respect, and alternative embodiments provide for determining the net error and using a set of independent conversion elements to subtract the net error from the overall output of the converter.

FIG. 5 shows an example of a static calibration, referred to as the first stage hereinabove, of a conversion element with respect to a reference conversion element. In this first stage, the DC current I2 is calibrated with respect to the current IREF. As mentioned, IREF is the DC current measured in the reference source, which may be I1, but is not necessarily. The switches are set so that the DC current meter measures the current difference and the calibration logic adjusts the source under calibration so that the measured current difference is minimized. In FIG. 5, three graphs are shown a)-c). Each graph is a plot of DC current measured (y-axis) against time (x-axis). In the left hand side of each graph the DC current measured when the master switch is set equal to zero is shown. When the master switch is set to its “zero” position, this arrangement is referred to herein below as mode 1, M1. In the right hand side of each graph, the DC current measured when the master switch is set to its “1” position. When the master switch is in this position, this arrangement is referred to herein below as mode 2, M2. It will be understood with reference to FIG. 4, that the master switch is in its “zero” position, when both portions of the switch 17 are in contact with contacts 21, and that the master switch is in its “1” position, when both portions of the switch are in contact with contacts 22.

In particular, FIG. 5 shows how the present invention measures a DC current offset error, Ierr. In graph a), the DC current measured in the IC_{P} circuit (or leg) is plotted against time. It is seen that in mode 1, the DC current measured in the IC_{P} circuit is equal to IREF and in mode 2, it is equal to I2. In graph b), the amount of error offset in the DC measurer, Ierr, is shown as a faint continuous line. Further, the graph b) shows the DC current measured in the IC_{N} circuit (or leg) plotted against time. It is seen that in mode 1, the DC current measured in the IC_{N} circuit is equal to I2 plus Ierr and in mode 2, the DC current measured in the IC_{N} circuit is equal to IREF plus Ierr. In the graph c), the difference between the DC currents measured in the IC_{P} circuit and the IC_{N} circuits are shown, IC_{P} minus IC_{N}. The difference between the DC current between the IC_{P} and the IC_{N} circuits in mode 1 is equal to IREF minus I2 minus Ierr, and in mode 2, the difference is equal to I2−IREF−Ierr. It has been found that by determining the difference between the currents measured in the two modes, the offset error, Ierr, is cancelled out, and that the difference between the modes is equal to two times the difference between IREF and I2. This is demonstrated below:

$$\begin{matrix}M1 - M2 = IREF - I2 - Ierr - ( I2 - IREF - Ierr ) \\ = 2 ( IREF - I2 ) .\end{matrix}$$

Thus, it has been found that by using a master switch as described above to switch between two modes, an offset error can be removed. It is noted that in the example described above with reference to FIG. 5, the offset error was introduced into one leg only (i.e. the IC_{N} leg). However, the invention is not limited in this respect, and it will be understood that the master switch according to the present invention functions to remove offset errors in the either other leg (i.e. the IC_{P} leg) or the difference between both legs. With respect to graph c), it is commented that the minus Ierr is shown as a faint continuous line.

The dynamic calibration is now described with reference to FIGS. 6 and 7. As mentioned, this second stage preferably comprises two stages: calibration with respect to the duty cycle as shown in FIG. 6 and with respect to the delay as shown in FIG. 7. It should be noted, in general, that the duty cycle calibration mode, described below, does not require a reference source. Calibration of the duty cycle only requires that a current source to be calibrated is provided and looked at, refer to FIG. 6. Hence, in the duty cycle calibration mode, the source selector switch for the reference source is also not required, and thus, preferably, in duty cycle calibration mode, the source selector switches the current to a dump line (not shown). As a further general comment, it is added that for static and dynamic calibration, the result of each calibration is required for the following step in the calibration. For example, the result of the static calibration is required for the calibration of the duty cycle, and the result of the calibration of the duty cycle is required for calibration of the delay. For example, once the static mismatch is now, the duty cycle may only be corrected if the signal for the now known static mismatch is corrected. Again, this may be done by adding the static correction signal to the source that is being calibrated. Alternatively, this may be carried out by the digital calibration logic 2. For example, once the static mismatch is known, the mismatch may be input to the digital calibration logic, so that if a signal is measured, the known mismatch representing the error may be digitally subtracted from the measured signal to yield the desired signal. In a similar way, once the duty cycle error is known, it too, may be input to the digital calibration logic 2, which will then account for this error in calibrating with respect to the delay.

FIG. 6 shows an example of the duty cycle calibration of a conversion element with respect to a reference conversion element. As for FIG. 5, FIG. 6 shows three graphs a)-c) where a DC offset error, Ierr, is present in the IC_{N} leg. Each graph a)-c) is a plot of current measured (y-axis) against time (x-axis). On the left hand side of each graph the current measured when the master switch is in its “zero” position. As above, this arrangement is referred to herein below as mode 1, M1. On the right hand side of each graph, the DC current measured when the master switch is in its “1” position is shown. When the master switch is in its “1” position, this arrangement is referred to herein below as mode 2, M2. The minus value of the DC offset error, −Ierr, is shown as a faint continuous line.

It is seen from FIG. 6 that the duty cycle of current source I2 is not even, that is, although, the input data is 010101 . . . , the current source I2 is in one position, I2+, for a longer duration than it is in the other position, I2−. When averaged over time, this leads to a DC error. It has been found that once the offset error, Ierr, has been removed using the technique described above, the DC error resulting from the duty cycle error can be measured, and a calibration signal derived on the basis of the measured error. Preferably, although it is not essential, the data stream for the source to be calibrated is changed continuously (010101010 . . . ). The average DC output current is measured twice by the DC current measurer. Once for the master switch in each of its positions. The difference between these two results, that is M1−M2, gives the duty cycle of the source to be calibrated, without taking account of the DC offset error, Ierr. Once the duty cycle is known it can be changed in various ways. In one embodiment the threshold of the clocked data signal in the latch is changed. For instance, if the threshold of the following circuitry (that is the circuitry responsive to the clocked data signal) is increased, it will take slightly longer for this circuitry to detect a low-to-high change in data signal while at the same time it will take slightly less time to detect a high-to-low change in data signal.

For example, in graph a) shown in FIG. 6, the current in the IC_{P} leg is measured. In graph b), the current in the IC_{N} leg is measured. It is seen that at time, t1, the current measured is that of the maximum of the longer duration position, I2+. At time, t2, the current measured is that of the minimum of the longer duration position, I2+, plus the offset error, Ierr. At time, t3, the current measured is that of the maximum in the position which is held for a shorter duration, I2−. At time, t4, the current measured is that of the minimum of the shorter duration position plus the offset error, Ierr. The graph c) shows the difference over time of the current measured in the IC_{P} leg and the IC_{N} leg. Line 60 shows the direct current (DC) difference between the current measured in the IC_{P} leg and the IC_{N} leg in mode 1 and line 61 shows the DC difference between the current measured in the IC_{P} leg and the IC_{N} leg in mode 2. It has been found that the difference between the DC difference measured in the two modes, that is the difference between the current value of lines 60 and 61, is equal to two times the error in the duty cycle. Thus, by determining the DC difference between the two modes, a calibration signal representing the calibration for the duty cycle error is generated to be input to the source for calibration I2.

The second stage of the dynamic calibration comprises calibrating a conversion element with respect to delay mismatch between sources. FIG. 7 shows an example of the switching delay calibration of a conversion element, 12, with respect to a reference conversion element, IREF. FIG. 7 shows five graphs a)-e). Each graph is a plot of current measured (y-axis) against time (x-axis). Graph a) shows a plot of the current produced by the reference source in one of the legs downstream of latch 8 (refer to FIG. 4) if the latch switches periodically. As described with reference to FIG. 1, the current through this leg is called IREF+ while the current through the other leg is called IREF−. Thus, at any one time, either one of these two legs will carry the current IREF, while the other is zero. The reference latch governs this process. The same nomenclature is assigned to the legs of the source to be calibrated. Thus, with reference to FIG. 7, for source number 2, the current in the first and second legs will be I2− and I2+, respectively. Here, it is assumed, that if the data signal of a latch is ‘1’, the latch will set the switches such that the ‘+’ leg carries the source current and the ‘−’ leg carries no current. And therefore if the data signal is ‘0’, the ‘−’ leg will carry the source current while the ‘+’ leg is zero.

Thus, graph 7a) shows the current through leg IREF+ during one cycle over time and graph 7b) shows the current through leg I2+ during the same cycle. If it is assumed that the same data signal is applied to the latches 8 of both sources I2 and IREF, then it is clearly seen that the latch of I2 is delayed by an amount t_{de} compared to the latch of IREF. It is now described how the DC current measurer in the calibration unit measures this delay t_{de}. To do this, firstly, the current through the IC_{P} leg is examined.

If the master switch is in the ‘0’ position it can be assumed that the IC_{P} leg is connected both to IREF+ and to I2− (refer to FIGS. 4 and 7c), and therefore the IC_{N} leg will be connected to IREF− and I2+. Obviously these connections will be exchanged when the master switch adopts the ‘1’ position, so IC_{P} is then connected both to IREF− and to I2+ and IC_{N} is connected to IREF+ and I2−. Now, because the ‘+’ and ‘−’ signs of the two different sources are always combined at the IC_{P} leg, only one of the source currents IREF and I2 will flow through IC_{P} if the data signal on both latches is equal. And the other source current flows through IC_{N}.

So, with the master switch in the ‘0’ position, the IC_{P} leg carries a combination of the currents carried by IREF+ and I2−, which is equal to the current generated by one source if the data signals are equal. But if the data signal is the same for both latches, yet alternating, for instance in a . . . 1100110011 . . . fashion, the current through the IC_{P} leg will not be constant anymore if there is a delay, such as the one shown in FIGS. 7a and 7b. The current through IC_{P} will temporarily become zero as shown in the first part of 7c when the data signal changes from high to low, because the latch of I2 is delayed compared to IREF.

Now if the data signal were to be changed back from a low to a high signal on both latches, IC_{P} would temporarily carry the current of both sources because the IREF latch would already switch the current back to the IREF+ leg while the I2 latch is delayed in taking the current away from the I2− leg. This situation, however, is prevented from happening by switching the master switch 10 in advance of the data signal changing from low to high. As a result the IC_{N} leg gets the double current while the IC_{P} leg receives zero again. This is shown in FIGS. 7c & 7d, where the switching of the master switch 10 is half a cycle behind the switching of the latches 8. So for instance, if the data signal applied to the latches 8 has the aforementioned . . . 110011001100 . . . pattern, the master switch 10 is arranged to switch according to the . . . 100110011001 . . . pattern.

Graph e) shows a plot over time of the output of the current difference measurer, which determines the current difference over time between IC_{P} and IC_{N}, that is IC_{P}−IC_{N}. The average DC current denoted by reference sign 70 is determined over time. It has been found that the delay error is proportional to the measured current. This is because the average measured current is I multiplied by the ratio of time delay and the time period, where I is equal to I2=IREF (n.b. I2 is calibrated to be equal to IREF), time delay (Tdelay) is equal to the unwanted delay, and the time period (Tperiod) is the time at which the master switch is in one position, for example, in mode 1. Therefore, strictly in order to determine the unwanted time delay (Tdelay) a calculation is required. However, this is not necessary because ultimately the error current is required to be determined, and not the time directly. For one switch, this error current is equal to I multiplied by the ratio of the unwanted time delay (Tdelay) and the clock duration (Tclock), with the clock duration (Tclock) being the period a single data sample takes. So, if the . . . 00110011 . . . pattern is used, the clock duration (Tclock) is equal to half of the time period (Tperiod) the master switch is in one position, and therefore, the error current that needs to be corrected is twice as large as the measured DC current. It will be understood that if the data pattern were, for example, 10 “zeros” followed by 10 ”“1s”, the error current needed would be 10 times than that measured. Thus, it becomes more difficult to accurately determine the error current. Therefore, preferably, the factor of the time period of the master switch in one position (Tperiod) to the clock duration (Tclock) is kept to the minimum, whereby a factor of two is preferably, so that the master switch can be half a cycle later than the latches in switching.

Thus, in short, it has been found that the delay error is proportional to the average DC current 70 minus the offset error, Ierr. In order to generate a calibration signal to correct for the delay error, the offset error, Ierr, the offset error is determined together with the error due to the switching of the master switch (which is not shown in the graphs in FIG. 7) for subtraction from the average DC current 70. This is achieved by not switching the sources to be calibrated and the reference source, but by choosing to switch for a certain period only the master switch.

Whilst specific embodiments of the invention have been described above, it will be appreciated that the invention may be practiced otherwise than as described. The description is not intended to limit the invention.

1. A digital to analog converter comprising:
at least two conversion elements;
and a conversion element selection unit for selecting in response to a multibit digital input signal from said at least two conversion elements a number of conversion elements for connection to an output unit for outputting an analog signal: and
a calibration unit for compensating mismatch between respective ones of said at least first and second conversion elements,
wherein said calibration unit is adapted to perform said mismatch compensation in response to a comparison of an output from at least one of said conversion elements with an output from a reference conversion unit.

2. A digital to analog converter according claim 1, wherein said calibration unit comprises a unit for calibrating said output of said at least one conversion element in response to said comparison of said output of said at least one conversion element with said output of said reference conversion means.

3. A digital to analog converter according to claim 1, wherein said calibration unit comprises a unit for adjusting said conversion element selection unit in response to said comparison.

4. A digital to analog converter according to claim 1, wherein said calibration unit comprises a unit for determining the difference between said output of said at least one conversion element and said output of said reference conversion element.

5. A digital to analog converter according to claim 2, wherein said calibration unit is adapted to adjust the duty cycle of the respective latch connecting said at least one conversion element to said output unit in response to said comparison.

6. A digital to analog converter according to claim 2, wherein said calibration unit is adapted to adjust the switching delay of the respective latch connecting said at least one conversion element to said output unit in response to said comparison.

7. A digital to analog converter according to claim 1, wherein said reference conversion element is additional to said at least two conversion elements.

8. A digital to analog converter according to claim 1, wherein said reference conversion element is selected from said at least two conversion elements.

9. A method of converting a digital signal to an analog signal converter comprising the steps of:
providing a plurality of conversion elements and a reference conversion element;
in response to said digital signal selecting from said at least two conversion elements a number of conversion elements;
combining the outputs of said selected conversion elements to provide an analog signal; and
calibrating for mismatch between respective ones of said plurality of conversion elements,
wherein an output from at least one of said conversion elements is compared with an output from a reference conversion unit and said calibrating step is carried out in response to said comparison.

10. The method of converting a digital input signal into an analog output signal according to claim 9, wherein said calibrating step includes the further step of modifying said selecting step in response to said comparison.

11. The method of converting a digital input signal into an analog output signal according to claim 12, wherein said calibrating step includes the further step of calibrating the output of said at least one conversion element in response to said comparison.

12. A mismatch calibration unit for a digital to analog converter comprising:
a comparison unit for comparing outputs of first and second conversion units when input to the unit, and
a calculation unit for providing mismatch calibration signal to said conversion units when connected to the output of said calculation unit in response to said comparison.

13. A mismatch calibration unit according to claim 12, wherein said calibration signal is representative of an amount by which one of said outputs must be adjusted so as to calibrate for static mismatch of said conversion elements.

14. A mismatch calibration unit according to claim 12, wherein said calibration signal is representative of an adjustment amount of the duty cycle or of the switching delay of a latch connecting one of said conversion elements to an output unit so as to calibrate for dynamic mismatch of said conversion elements.
